(19) United States
(12) Patent Application Publication
(10) Pub. No.: US 2025/0318341 A1
(43) Pub. Date: Oct. 9, 2025

(54) Manufacturing Method for Color Photodiodes in Parallel Communication, Color Photodiode, and Photoelectric Display Screen

(71) Applicants: Wei SHEN, Shenzhen (CN); Ke CHEN, Shenzhen (CN)

(72) Inventors: Wei SHEN, Shenzhen (CN); Ke CHEN, Shenzhen (CN)

(21) Appl. No.: 18/777,582

(22) Filed: Jul. 19, 2024

(30) Foreign Application Priority Data
Apr. 8, 2024 (CN) 202410410018.2

(51) Int. Cl. H01L 27/15; H01L 33/62

(52) U.S. Cl. CPC H10H 29/142; H10H 20/857; H10H 20/0364

(57) ABSTRACT

In a manufacturing method for the color photodiodes in parallel communication, an integrated support includes a plurality of single support modules; on each single support module, there is a base and a plurality of pins installed thereon, and there are packaging cavities on the base; in each packaging cavity, the visible light emitting chip and the color control chip are fixed and installed; the color control chip is the three-channel parallel-driven chip; the three-channel parallel-driven chip has three channels, which are used to control and drive the red light emitting chip, the blue light emitting chip, and the green light emitting chip respectively; the visible light emitting chip, the color control chip, and the pins are welded with the bonding wire to form the electric control loop; the packaging cavities are dispensed with the packaging adhesive, and cured and molded; and the integrated support after curing and molding is cut.

### CROSS REFERENCE TO THE RELATED APPLICATIONS

This application is based upon and claims priority to Chinese Patent Application No. 202410410018.2, filed on Apr. 8, 2024, the entire contents of which are incorporated herein by reference.

### TECHNICAL FIELD

The present invention relates to the photodiodes, in particular to a manufacturing method for the color photodiodes in parallel communication, a color photodiode, and a photoelectric display screen.

### BACKGROUND

With the continuous development of science and technology, photodiode as a new-generation light source is applied in a more and more extensive range, and has been deeply involved in the people's work and life. In the field of photoelectric display, photodiode, as an important light-emitting element, plays a vital role.

Due to the limitation of their control chip, the general color photodiodes can only be used for series communication. Despite the simplicity and high efficiency, this communication mode is also defective to certain extent. In the application to the display screen, if one or more color photodiodes are damaged, all the color diodes on the whole series communication circuit will fail, so that the display screen is unable to operate normally, affecting the user experience.

In order to solve the problem, some manufacturers have launched the color photodiodes with the backup communication function. This diode is designed with the backup communication circuit, which will be started when a color photodiode is damaged, so that the other undamaged diodes are still able to operate normally, so as to guarantee the normal service of the whole display screen. If two or more color photodiodes are damaged, all the color diodes on the series communication circuit will also fail.

However, due to the complex structure, the color photodiode with the backup communication function is limited in size, and it is impossible to manufacture such color photodiode in the size less than 2 mm. This may cause certain constraints for some precision electronic products with strict requirements for size.

### SUMMARY

The present invention is intended to solve, at least to a certain extent, one of the technical problems in the related technology. To this end, the present invention aims to provide a manufacturing method for the color photodiodes in parallel communication, a color photodiode, and a photoelectric display screen.

To achieve the aforesaid purposes, on the one hand, the manufacturing method for the color photodiodes in parallel communication according to the embodiment of the present invention includes:

An integrated support is provided; the said integrated support includes a plurality of single support modules, and a plurality of said single support modules are injection molded; on each said single support module, there is a base and a plurality of pins installed on the said base, and there are packaging cavities on the said base;

In each said packaging cavity, the visible light emitting chip and the color control chip are fixed and installed; the said visible light emitting chip includes red light emitting chip, blue light emitting chip, and green light emitting chip; the said color control chip is the three-channel parallel-driven chip; the said three-channel parallel-driven chip has three channels, which are used to control and drive the red light emitting chip, the blue light emitting chip, and the green light emitting chip respectively;

The said visible light emitting chip, the color control chip, and the pins are welded with the bonding wire to form the electric control loop;

The said packaging cavities are dispensed with the packaging adhesive, so as to package the said visible light emitting chip and color control chip into the said packaging adhesive;

The integrated support after curing and molding is cut into a plurality of color photodiodes, and each said color photodiode includes a single support module.

In addition, the manufacturing method for the color photodiodes in parallel communication according to the aforesaid embodiment of the present invention may also have the following additional technical characteristics:

According to one embodiment of the present invention, the said visible light emitting chip and color control chip fixed and installed in each said packaging cavity include:

The chip fixing adhesive is dispensed at first designated position and the second designated position in the said packaging cavity respectively;

The red light emitting chip, the blue light emitting chip, and the green light emitting chip are placed at the said first designated position, and the predetermined distance is maintained, and the said red light emitting chip, blue light emitting chip and green light emitting chip are bonded with the said chip fixing adhesive;

The color control chip is placed at the second designated position, and the said induction chip is bonded with the chip fixing adhesive;

The said integrated support is delivered into a curing device and baked at the temperature of 150-180° C. for 60-80 minutes for curing.

According to an embodiment of the present invention, there are three said pins, including a positive power pin, a negative power pin, and a signal input pin; the said color control chip includes a positive terminal, a negative terminal, a signal input terminal, a first driving terminal, a second driving terminal, and a third driving terminal;

The said visible light emitting chip, color control chip and pins are welded with the bonding wire to form the electric control loop, including:

The said positive terminal is welded with the said positive power pin, the said negative terminal is welded with the said negative power pin, and the said signal input terminal is welded with the said signal input pin;

The said first driving terminal is electrically connected with the negative pole of the said red light emitting chip, and the said second driving terminal is electrically connected with the negative pole of the said green light emitting chip, and the said third driving terminal is electrically connected with the negative pole of the said blue light emitting chip;

The positive poles of the said red light emitting chip, green light emitting chip and blue light emitting chip are connected with the said positive power pins.

According to an embodiment of the present invention, the said packaging cavity is dispensed with the said packaging adhesive, and cured and molded, including:

The epoxy resin adhesive or the silica gel is used to dispense and package the packaging cavity;

The integrated support dispensed and packaged is transferred to the baking equipment, so as to bake and cure the integrated support at a predetermined temperature.

According to an embodiment of the present invention, the integrated support dispensed and packaged is transferred to the baking equipment, so as to bake and cure the integrated support at a predetermined temperature, including:

The integrated support dispensed and packaged is baked in the first stage; in the said first stage, the baking temperature is 60-100° C., and the baking time is 60-80 minutes;

The integrated support dispensed and packaged is baked in the second stage; in the said second stage, the baking temperature is 140-160° C., and the baking time is 60-80 minutes.

According to an embodiment of the present invention, after the integrated support cured and molded is cut, it also includes:

The color photodiodes formed after cutting are baked to remove the moisture produced during the process of cutting.

According to an embodiment of the present invention, the said color photodiodes are baked at a temperature of 60-100° C. and for 60 to 80 minutes.

On the other hand, the color photodiodes according to the embodiment of the present invention are manufactured by the method described above.

On the other hand, the photoelectric display screen according to the embodiment of the present invention has a plurality of color photodiodes as described above, and a plurality of the said color photodiodes are driven by means of parallel communication.

The manufacturing method for the color photodiodes in parallel communication, the color photodiode, and the photoelectric display screen are provided according to the embodiments of the present invention; by the method described above, the parallel-driven color photodiodes can be manufactured and formed; in the application to the display screen, a plurality of color photodiodes can be communicated with each other in parallel, so that the normal operation of other color photodiodes will not be affected in the event that one or more LED lamps are damaged, so as to guarantee the normal service of the whole display screen. Furthermore, the separate gray-scale and cascade control of the chip can be achieved by parallel communication. In addition, due to the simple structure of the color photodiode, the small-size packaging can be guaranteed, so as to adapt to the display screen and other precision electronic products with strict requirements for size.

Some additional aspects and advantages of the present invention will be given in the Description below, and some additional aspects and advantages will become apparent from the Description below, or will be learned through the practice of the present invention.

### BRIEF DESCRIPTION OF THE DRAWINGS

In order to make a clearer explanation to the technical scheme in the embodiments of the present invention or in the prior art, the appended drawings to be used in the embodiments or description of the prior art are briefly introduced below. It is obvious that the appended drawings described below are only certain embodiments recorded in the present invention, and the ordinary persons skilled in the art can also obtain other appended drawings on the basis of the structures shown in such appended drawings without the contribution of creative labor.

FIG. 1 is the flow chart for manufacturing method for the color photodiodes in parallel communication in the embodiments of the present invention;

FIG. 2 is the schematic diagram for top of the color photodiode (With packaging adhesive removed) in the embodiments of the present invention;

FIG. 3 is the schematic diagram for the pins of the color photodiode in the embodiments of the present invention;

FIG. 4 is the schematic diagram for bottom of the color photodiode in the embodiments of the present invention;

FIG. 5 is the equivalent circuit diagram for the color photodiode in the embodiments of the present invention;

FIG. 6 is the real product picture of the color photodiode (front and back) in the embodiments of the present invention.

Legend in appended drawings:
10. Single support module;
101. Base;
102. Positive power pin;
102a. First welding zone;
102b. Positive welding zone;
102c. Vacant zone;
103. Negative power pin;
103a. Second welding zone;
103b. Negative welding zone;
104. Signal input pin;
104a. Third welding zone;
104b. Signal input welding zone;
20. Color control chip;
30. Red light emitting chip;
31. Green light emitting chip;
32. Blue light emitting chip.

The realization of the purpose, the functional characteristics and advantages of the present invention will be further explained in conjunction with the embodiments and with reference to the appended drawings.

### DETAILED DESCRIPTION OF THE EMBODIMENTS

The embodiments of the present invention are described in detail below, the examples of the said embodiments are shown in the appended drawings, where identical or similar labels are used to indicate the identical or similar ts or the components with identical or similar functions from beginning to end. The embodiments described below with reference to the appended drawings are exemplary and intended to interpret the present invention, and shall not be construed as the limitations on the present invention. Based on the embodiments of the present invention, all other embodiments obtained by ordinary skilled persons in the art without contribution of creative labor shall fall within the protection scope of the present invention.

In the description of the present invention, it shall be understood that the oriental and positional relationship indicated by the terms such as “center”, “longitudinal”, “transverse”, “length”, “width”, “thickness”, “up”, “down”, “front”, “rear”, “left”, “right”, “vertical”, “horizontal”, “top”, “bottom”, “inside”, “outside”, “clockwise”, “counterclockwise”, “axial”, “circumferential”, and “radial” are based on the oriental and positional relationship indicated in the appended drawings, and for description of the present invention and simplification of the description only, but not intended to indicate or imply that the device or component referred to must have a particular orientation, and must be constructed and operated in a particular orientation. Therefore, such oriental and positional relationship shall not be interpreted as the limitation on the present invention.

In addition, the terms “first” and “second” shall be used for descriptive purpose only, and shall not be understood to indicate or imply relative importance or to indicate implicitly the quantity of the technical features as indicated. Thus, a feature defined as “first” or “second” may include, explicitly or implicitly, one or more such features. In the description of the present invention, “multiple” means two or more unless otherwise expressly defined.

In the present invention, unless otherwise expressly specified and defined, the terms “installation”, “association”, “connection”, and “fixing”, shall be understood in a broad sense; for example, it includes fixed connection, or detachable connection, or integrated connection;

mechanical connection, or electrical connection; direct connection, or indirect connection through an intermediate medium, or connection within two components. For ordinary skilled persons in the art, the specific meaning of the above terms in the present invention can be understood according to the specific circumstances.

In the present invention, unless otherwise expressly specified and defined, the first feature may include direct contact between the first and second features “above” or “under” the second features, or may include contact between the first and second features not directly but through another feature between them. Furthermore, the first feature “above”, “over” and “on” the second feature include the first feature being directly above and diagonally above the second feature, or simply indicating that the first feature is higher in level than the second feature. The first feature “under”, “below” and “underneath” the second feature include the first feature being directly below and diagonally below the second feature, or simply indicating that the first feature is lower in level than the second feature.

The manufacturing method for the color photodiodes in parallel communication, the photodiode, and the photoelectric display screen in the embodiments of the present invention are described in detail below with reference to the appended drawings.

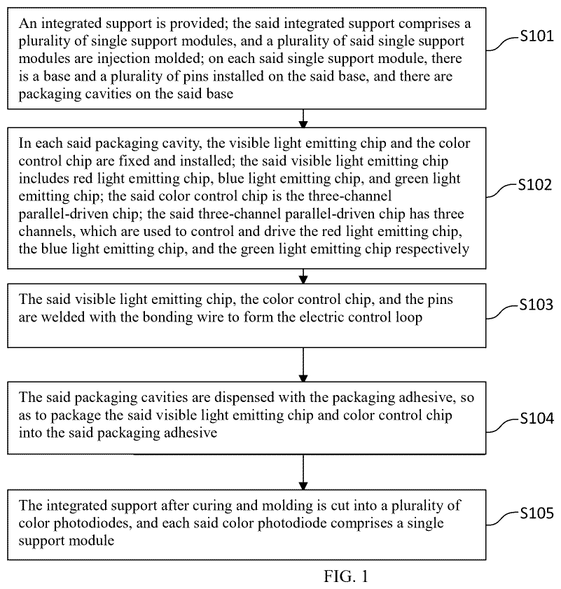

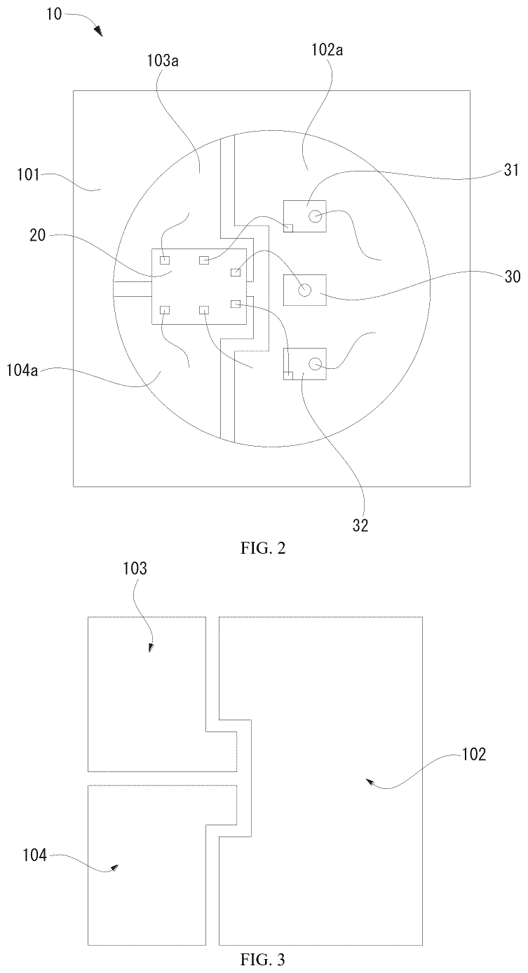

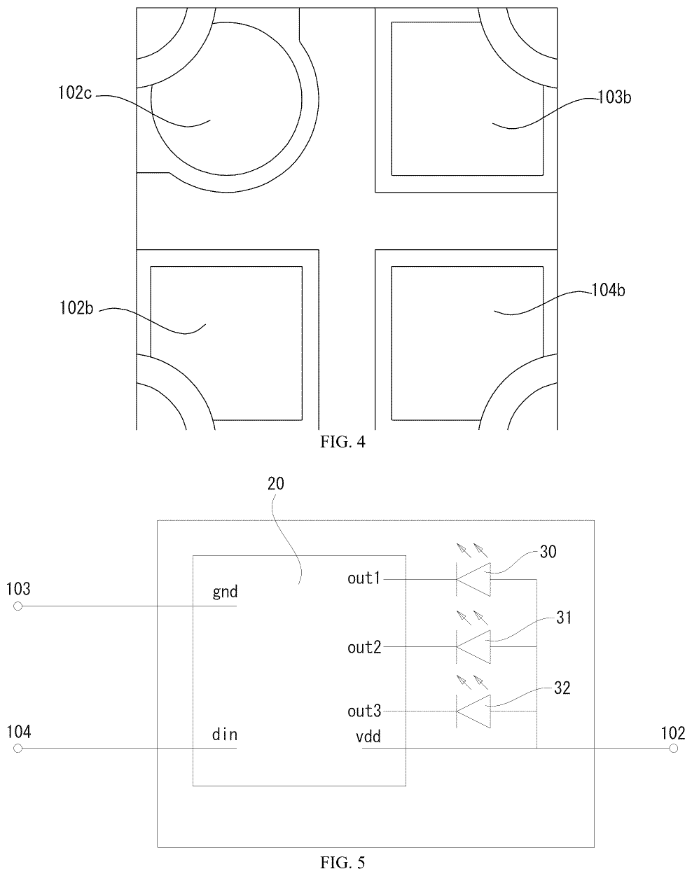

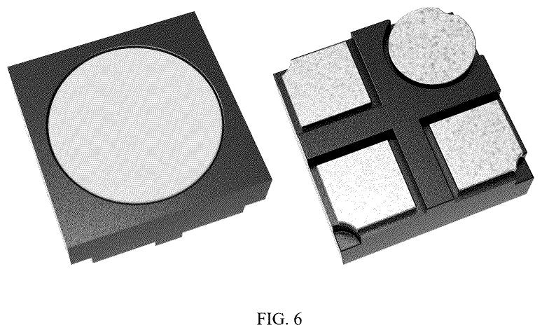

With reference to FIG. 1 and as shown in FIG. 2 to FIG. 6, the manufacturing method for the color photodiodes in parallel communication provided according to the embodiments of the present invention includes:

S101. An integrated support is provided; the said integrated support includes a plurality of single support modules 10, and a plurality of said single support modules 10 are injection molded; on each said single support module 10, there is a base 101 and a plurality of pins installed on the said base 101, and there are packaging cavities on the said base 101.

Specifically, the integrated support can be manufactured and molded by the following method:

First, the conductive metal foil is used as the raw material. Under the stamping action of the high-precision die, the metal foil is cut and divided into the shape of pin as required. Next, the injection forming mold is prepared, the mold cavity is shaped like the shape of the integrated support as required, and then the metal foil with pins is fixed in the mold cavity. Finally, the thermoplastic raw material is melted and injected into the mold cavity; after the plastic is cooled down and cured, the integrated support is molded by injection. This integrated injection molding process can not only guarantee the high-precision assembly of the pin and the base 101, but also improve the production efficiency to a great extent, ensuring that a plurality of single support modules are formed on the integrated support, which is conducive to large-scale automated production.

S102. The visible light emitting chip and the color control chip 20 are fixed and installed in each said packaging cavity. The said visible light emitting chip includes red light emitting chip 30, blue light emitting chip 32, and green light emitting chip 31; the said color control chip 20 is the three-channel parallel-driven chip; the said three-channel parallel-driven chip has three channels, which are used to control and drive the red light emitting chip 30, the blue light emitting chip 32, and the green light emitting chip 31 respectively

Exemplarily, the red, green and blue light-emitting chips and the color driver chip can be fixed respectively in the packaging cavity on the base 101 of each single support module 10 with the high-precision automation equipment, and the installation positions are accurate. The chips can be fixed by surface mounting and welding or conductive adhesive bonding. The three light emitting chips shall be distributed at intervals to avoid obscuring each other.

S103. The said visible light emitting chip, the color control chip 20, and the pin are welded with the bonding wire to form the electric control loop. At this step, the automatic wire bonder can be used to weld the visible light emitting chip, the color control chip 20 and the pins with gold wire or silver wire and other bonding wires according to the equivalent circuit diagram to form the color electric control loop. The color electric control loop allows the external circuit to communicate with the photodiodes via pins.

The color control chip 20 adopts the three-channel parallel-driven chip. The three-channel parallel-driven chip has three mutually independent channels connected in parallel, i.e. the first channel, the second channel, and the third channel, corresponding to the red light, the green light and the blue light respectively. The three channels are used to control the red, green and blue light-emitting chip respectively to achieve independent modulation of light in three primary colors, so as to produce different color mixing effects. The first channel is used to control the luminous parameters of the red light emitting chip 30 independently, the second channel is used to control the luminous parameters of the green light emitting chip 31 independently, and the third channel is used to control the luminous parameters of the blue light emitting chip 32 independently. The output current of the aforesaid three channels can be adjusted dynamically by analog or digital control signals outside the chip, so as to achieve continuous step-less adjustment of the brightness of the corresponding light emitting chip.

S104. The packaging adhesive is used to dispense the said packaging cavity for curing and molding, so as to package the said visible light emitting chip and the color control chip 20 in the said packaging adhesive.

Exemplarily, an appropriate amount of transparent packaging adhesive such as epoxy resin and silica gel can be dispensed accurately into each packaging cavity, so as to cover the chip area completely. Then, the heating and curing treatment shall be carried out to cure and mold the packaging adhesive thoroughly, and package the chip into the packaging adhesive firmly, so as to prevent physical damage and environmental impact, such as dust, moisture and mechanical shock; at the same time, after curing, such epoxy resin adhesive or silica gel can form a hard protective layer with excellent light transmission, so as to guarantee the optical effect of the photodiode.

S105. The integrated support after curing and molding is cut to form a plurality of color photodiodes, and each said color photodiode includes a single support module 10.

At this step, after the packaging adhesive is cured and cooled down completely, the whole integrated support can be placed on the high-precision cutting machine, and then cut at the pre-set position. The cutting position is aligned precisely to the boundary region of each single support module 10, so as to cut and separate the whole integrated support into a polarity of individual and independent color photodiodes in one operation.

The color photodiodes manufactured and formed by the aforesaid method can be driven in parallel independently. In the specific working process, the external microcontroller or the digital circuit first calculates the ratio of the three primary colors including red, green and blue according to the color to be synthesized, and sends the corresponding analog or digital control signal to the three channels respectively. After receiving the control signal, the control circuit inside the three channels will adjust the constant current value output accordingly, so that the brightness of the red, green and blue light-emitting chips will change at the preset ratio. The lights of the three different primary colors are superimposed at the corresponding luminous intensity, and the target color is finally produced after the color mixing and the subsequent uniform mixing of the packaging adhesive. By changing the value of the control signal, the luminance ratio of the three primary colors will change dynamically, so as to achieve the step-less color tuning and the synthesis of the luminous effects in various colors.

The manufacturing method for the color photodiodes in parallel communication is provided according to the embodiments of the present invention. By the method described above, the parallel-driven color photodiodes can be manufactured and formed; in the application to the display screen, a plurality of color photodiodes can be communicated with each other in parallel, so that the normal operation of other color photodiodes will not be affected in the event that one or more LED lamps are damaged, so as to guarantee the normal service of the whole display screen. Furthermore, the separate gray-scale and cascade control of the chip can be achieved by parallel communication. In addition, due to the simple structure of the color photodiode, the small-size packaging can be guaranteed, so as to adapt to the display screen and other precision electronic products with strict requirements for size.

In one embodiment of the present invention, the step S102 includes:

The chip fixing adhesive is dispensed at the first designated position and the second designated position in the said packaging cavity respectively. The two designated positions can be pre-determined in the packaging cavity for installation of the visible light emitting chip and the color control chip 20 respectively. The automatic dispensing equipment is used to dispense a certain amount of chip fixing adhesive at the first designated position and the second designated position respectively.

The red light emitting chip 30, the blue light emitting chip 32, and the green light emitting chip 31 are placed at the said first designated position, and the predetermined distance is maintained, and the red light emitting chip 30, the blue light emitting chip 32, and the green light emitting chip 31 are bonded with the said chip fixing adhesive. That is, the red light emitting chip 30, the blue light emitting chip 32, and the green light emitting chip 31 are distributed and placed on the chip fixing adhesive at the first designated position at the uniform spacing. The light-emitting chip can be fixed firmly in the packaging cavity with the help of the bonding action of the chip fixing adhesive.

The color control chip 20 is placed at the second designated position, and the said Hall induction chip is bonded with the chip fixing adhesive. That is, the color control chip 20 is accurately placed on the chip fixing adhesive at the second designated position, adjacent to the position of the light-emitting chip but at a certain interval. Similarly, the color control chip 20 is fixed in the packaging cavity with the help of the bonding action of the chip fixing adhesive.

The said integrated support is delivered into the curing device and baked at the temperature of 150-180° C. for 60-80 minutes for curing. At this step, by baking at the temperature ranging from 150 to 180° C. for 60 to 80 minutes, the chip fixing adhesive can be cured completely to form a solid structure, so as to maintain the stability of the color control chip 20 and the visible light emitting chip in the service for a long term. The combination of temperature and time is selected on an experimental basis to improve the performance of the chip fixing adhesive to the maximum extent, while protecting the color control chip 20 and the visible light emitting chip from thermal damage.

Through the above steps, it is possible to ensure that the color control chip 20 and the visible light emitting chip shall be fixed in the support reliably, so as to ensure the quality of such color photodiodes during the process of manufacturing and the performance of such color photodiodes in the final application. Moreover, it is helpful to improve the reliability and durability of the product, and the simple process results in the optimized production efficiency and cost control.

In some embodiments of the present invention, as shown in FIG. 2 to FIG. 5, there are three pins; the said three pins include a positive power pin 102, a negative power pin 103, and a signal input pin 104; the said color control chip 20 includes a positive terminal vdd, a negative terminal gnd, a signal input end din, a first driving terminal out1, a second driving terminal out2, and a third driving terminal out3.

The said step S103 includes:

Weld the said positive terminal vdd with the said positive power pin 102, weld the said negative terminal gnd with the said negative power pin 103, and weld the said signal input din with the said signal input pin 104. Exemplarily, the automatic wire bonder is used to weld one end of the bonding wire to the positive terminal vdd of the color control chip 20, weld electrically the other end to the positive power pin 102 to connect the positive terminal vdd of the color control chip 20 with the positive power pin 102, so as to provide the color control chip 20 with the positive voltage of the external power. The bonding wire is also used to weld the negative terminal of the color control chip 20 with the negative power pin 103 reliably, so as to provide the color control chip 20 with the negative loop of power. In addition, the bonding wire is used to weld the signal input terminal din of the color control chip 20 with the signal input pin 104, in order to receive the external analog or digital control signal.

Connect electrically the said first driving terminal out1 with the negative pole of the said red light emitting chip 30, connect electrically the second driving terminal out2 with the negative pole of the said green light emitting chip 31, and connect electrically the third driving terminal out3 with the negative pole of the blue light emitting chip 32. Since the first driving terminal out1, the second driving terminal out2 and the third driving terminal out3 are used to drive the three light emitting chips respectively, it is necessary to use the bonding wire to weld the first driving terminal out1 with the negative pole of the red light emitting chip 30, weld the second driving terminal out2 with the negative pole of the green light emitting chip 31, and weld the third driving terminal out3 with the blue light emitting chip 32.

Connect the positive pole of the said red light emitting chip 30, the said green light emitting chip 31, and the said blue light emitting chip 32 with the said positive power pin 102. The positive pole of the red, green and blue light-emitting chips shall be connected electrically with the positive power pin 102 through the bonding wire, in order to obtain the positive voltage power supply from the external power.

By the aforesaid precision welding, a complete circuit connection is established between the color control chip 20, the light emitting chips and the pins. The three channels inside the color control chip 20 are connected with the red, green and blue light-emitting chips respectively, so as to control their driving current independently; at the same time, the color control chip 20 is also connected with the pin, so as to receive external control signals and power supply.

Preferably, the said positive power pin 102 has a first welding zone 102a located in the said packaging cavity, the said negative power pin 103 has a second welding zone 103a located in the packaging cavity, and the said signal input pin 104 has a third welding zone 104a located in the packaging cavity. The three-channel parallel-driving chip 20 is installed in the said second welding zone 103a and/or the said third welding zone 104a, and the said red light emitting chip 30, the said green light emitting chip 31 and the said blue light emitting chip 32 are installed in the said first welding zone 102a. With this layout, the positive power pin 102, the negative power pin 103 and the signal input pin 104 are distributed in a reasonable manner, so as to facilitate the welding between the color control chip 20, the visible light emitting chip and the pins, and guarantee the stability and reliability of the overall electrical system of the color control chip 20 and the visible light emitting chip.

In addition to the first welding zone 102a, the second welding zone 103a and the third welding zone 104a formed by the said three pins in the packaging cavity and used to connect the three-channel parallel-driven chip and the visible light emitting chip, there are corresponding welding zones of the tree pins on the bottom of the base 101, including the positive welding zone 102b, the negative welding zone 103b and the signal input welding zone 104b, which are used connect with external circuits.

Specifically, the positive power pin 102 forms a positive welding zone 102b on the bottom of the base 101. This metal bonding pad area can be welded directly to the positive pole of the external driving power to supply the positive voltage to the whole photodiode system. The negative power pin 103 forms a negative welding zone 103b on the bottom of the base 101. The metal bonding pad area can be connected with the negative pole of the external driving power to supply the negative reference voltage and the current loop for the system. The signal input pin 104 also forms a signal input welding zone 104b on the bottom of the base 101. This metal bonding pad area can be connected with the signal output terminal of the external control circuit or the microcontroller to receive PWM dimming signal or digital control bus signal that controls the color of the photodiode.

With the above structure, the positive welding zone 102b, the negative welding zone 103b, and the signal input welding zone 104b are integrated with the corresponding pins and base 101 to form an overall structure, so as to realize the highly integrated connection between the photodiode and the external power supply and the control circuit, which is conducive to the modular assembly. In addition, it is worth mentioning that the pins do not extend out of the base 101, so that it can be used for the products with high precision requirements such as the display screen with matrix diode arrangement.

Exemplarily, the positive power pin 102 also forms a vacant zone 102c on the bottom of the base 101.

In one embodiment of the present invention, the said packaging cavity is dispensed with the packaging adhesive, and cured and molded, including:

The packaging cavity is dispensed and packaged with epoxy resin adhesive or silica gel. As a kind of packaging material, epoxy resin adhesive or silica gel has excellent light transmission, and can form a hard and transparent protective layer after curing.

The integrated support dispensed and packaged is transferred into the baking equipment, so as to bake such integrated support at the predetermined temperature for curing. That is, after the dispensing, the whole integrated support shall be transferred rapidly into the dedicated baking equipment for curing treatment at the predetermined high temperature. The molecules of the packaging adhesive will undergo the cross-linking reaction and curing gradually, and become a hard and transparent solid polymer finally. After the high temperature curing for a predetermined period of time, the heating can be shut down, and the packaging adhesive will be cooled down thoroughly, so as to complete the curing.

By the above packaging adhesive dispensing and curing process, the visible light emitting chip and the color control chip 20 are covered in a transparent resin or silica gel protective layer permanently and firmly. On the one hand, the protection of the packaging adhesive can prevent the external environment such as dust, moisture, impact and other factors from causing damage to the chip, so as to extend the service life to a great extent; on the other hand, due to its excellent light transmission, it will not affect the light emitting function and luminance output of the chip.

In one embodiment of the present invention, the integrated support dispensed with the packaging adhesive is transferred into the baking equipment, so that it is baked at the predetermined temperature for curing, including:

The integrated support dispensed and packaged is baked in the first stage; in the said first stage, the baking temperature is 60-100° C., and the baking time is 60-80 minutes;

The integrated support dispensed and packaged is baked in the second stage; in the said second stage, the baking temperature is 140-160° C., and the baking time is 60-80 minutes.

Baking and curing is a process to be controlled in a precise way. The selection of temperature and time has an immediate impact on performance of the packaging material and the final protection effect. Too high temperature or too long time may result in the performance degradation of the packaging material, while too low temperature or too short time may result in the incomplete curing of the packaging material.

In this embodiment, the curing process of dispensing and packaging is divided into two baking stages, i.e. the baking at the first stage and the baking at the second stage. At the first stage of baking, the baking temperature is 60-100° C., and the baking time is 60-80 minutes. This temperature range is selected for gradual curing and drying of epoxy resin adhesive or silica gel. In this baking process, the solvent or volatile components in epoxy resin adhesive or silica gel are gradually evaporated, making the colloidal material stronger and bonded tightly to the support. At the second stage of baking, the baking temperature is 140-160° C., and the baking time is 60-80 minutes. The high temperature is helpful to cure and reinforce epoxy resin adhesive or silica gel to ensure its adhesion with the support and its stability. This baking process is also helpful to improve the heat resistance and weather resistance to adapt to various working environments and conditions.

By baking and curing at such two stages, epoxy resin adhesive/silica gel of the color photodiodes packaged can achieve the curing and stabilizing effect as required, so as to ensure that the color photodiodes shall have good performance, reliability and durability in use.

In one embodiment of the present invention, after cutting the integrated support cured and molded, it also includes:

The color photodiodes formed after cutting are baked to remove the moisture produced during the process of cutting.

It is easy to pick up a small amount of moisture during the process of cutting, and the residual moisture on the cutting surface may adversely affect the service life and the reliability of the devices. Therefore, in this embodiment, after the cutting is completed, the single color photodiode so cut open shall undergo a special baking procedure to remove the moisture produced during the process of cutting. By changing the baking procedure, any residual moisture on the cutting surface can be discharged and evaporated completely, so as to achieve the purpose of drying. This step is very important because even a very small 1 amount of residual moisture may cause cracking and enter the chip during subsequent use due to thermal expansion and contraction, thus affecting the service life of the device.

Advantageously, the color photodiodes after cutting shall be baked at the temperature of 60-100° C. and for 60-80 minutes. Such temperature and time shall be set according to the thermal curing characteristics of epoxy resin adhesive or silica gel, and the resistance of the chip to high temperature. In this temperature range, it is possible to remove moisture effectively without excessive thermal damage to the packaging adhesive and the chip.

As shown in FIG. 2 to FIG. 6, the embodiments of the present invention also provide a kind of color photodiode, which is manufactured by the method described above. The color photodiode can achieve the parallel-driven control, and separate gray-scale and cascade control; in the applications such as the display screen, a plurality of color photodiodes can be communicated with each other in parallel, so that the normal operation of other color photodiodes will not be affected in the event that one or more LED lamps are damaged, so as to guarantee the normal service of the whole display screen.

In addition, in some embodiments, gamma verification algorithm is built into the three-channel parallel-driven chip to improve the gray scale and achieve high gray driving display. It is possible to encode its address with the peripheral burning device, and control LED driving by parallel communication of single-chip microcomputer to realize the separate gray-scale and cascade control of the chip, and the constant current value and the pulse width modulation gray scale value output from each driving terminal can be set separately by commands.

The embodiments of the present invention also provide a kind of photoelectric display screen with a plurality of the color photodiodes as described above, and a plurality of the said color photodiodes are driven by means of parallel communication.

The photoelectric display screen provided according to the embodiments of the present invention has the aforesaid color photodiodes, and a plurality of color photodiodes can be communicated with each other in parallel, so that the normal operation of other color photodiodes will not be affected in the event that one or more LED lamps are damaged, so as to guarantee the normal service of the whole display screen. Furthermore, the separate gray-scale and cascade control of the chip can be achieved by parallel communication. In addition, due to the simple structure of the color photodiode, the small-size packaging can be guaranteed, so as to adapt to the display screen and other precision electronic products with strict requirements for size.

In the description of this Secification, the description with the terms such as “an embodiment”, “some embodiments”, “examples”, “specific examples”, or “some examples” means that the specific features, structures, materials, or characteristics described on the basis of such emobidments or examples are included in at least one embodiment or example of the present invention. In this Specification, the schematic representations of the above terms must not be directed to the same embodiments or examples. Furthermore, the specific features, structures, materials or characteristics so described may be combined in a suitable manner in any one or more embodiments or examples. In addition, without the conflict with each other, the persons skilled in the art may incorporate and combine the different embodiments or examples described in this Specification and the characteristics of different embodiments or examples.

Only the preferred embodiments of the present invention are described above without limitation on the claims of the present invention. All equivalent structure transformations made under the inventive concept of the present invention and with the contents of the Specification and the appended drawings of the present invention, or the direct/indirect application thereof in other related technical fields are included within the scope of patent protection of the present invention.

What is claimed is:

1. A manufacturing method for color photodiodes in parallel communication, comprising:
arranging an integrated support, wherein the integrated support comprises a plurality of single support modules, and the plurality of single support modules are injection molded; on each single support module of the plurality of single support modules, there is a base and a plurality of pins installed on the base, and there are packaging cavities on the base;
fixing and installing a visible light emitting chip and a color control chip in each packaging cavity of the packaging cavities, wherein the visible light emitting chip comprises a red light emitting chip, a blue light emitting chip, and a green light emitting chip; the color control chip is a three-channel parallel-driven chip; the three-channel parallel-driven chip has three channels, wherein the three channels are used to control and drive the red light emitting chip, the blue light emitting chip, and the green light emitting chip respectively;
welding the visible light emitting chip, the color control chip and the plurality of pins with a bonding wire to form an electric control loop;
dispensing the packaging cavities with a packaging adhesive to package the visible light emitting chip and the color control chip into the packaging adhesive; and
cutting the integrated support after curing and molding into a plurality of color photodiodes, wherein each color photodiode of the plurality of color photodiodes comprises a single support module.

2. The manufacturing method for the color photodiodes in parallel communication according to claim 1, wherein the step of fixing and installing the visible light emitting chip and the color control chip in each packaging cavity comprises:
dispensing a chip fixing adhesive at a first designated position and a second designated position in the packaging cavity respectively;
placing the red light emitting chip, the blue light emitting chip and the green light emitting chip at the first designated position, maintaining a predetermined distance, and bonding the red light emitting chip, the blue light emitting chip and the green light emitting chip with the chip fixing adhesive;
placing the color control chip at the second designated position, and bonding an induction chip with the chip fixing adhesive; and
delivering the integrated support into a curing device and baking the integrated support at a temperature of 150° C.-180° C. and for 60 minutes-80 minutes for curing.

3. The manufacturing method for the color photodiodes in parallel communication according to claim 1, wherein the plurality of pins comprise a positive power pin, a negative power pin, and a signal input pin; the color control chip comprises a positive terminal, a negative terminal, a signal input terminal, a first driving terminal, a second driving terminal, and a third driving terminal;
the step of welding the visible light emitting chip, the color control chip and the plurality of pins with the bonding wire to form the electric control loop comprises:
welding the positive terminal with the positive power pin, welding the negative terminal with the negative power pin, and welding the signal input terminal with the signal input pin;
electrically connecting the first driving terminal with a negative pole of the red light emitting chip, electrically connecting the second driving terminal with a negative pole of the green light emitting chip, and electrically connecting the third driving terminal with a negative pole of the blue light emitting chip; and
connecting a positive pole of the red light emitting chip, a positive pole of the green light emitting chip and a positive pole of the blue light emitting chip with the positive power pin.

4. The manufacturing method for the color photodiodes in parallel communication according to claim 1, wherein the step of dispensing the packaging cavity with the packaging adhesive and curing and molding comprises:
using an epoxy resin adhesive or a silica gel to dispense and package the packaging cavity; and
transferring the integrated support dispensed and packaged into a baking equipment to bake and cure the integrated support at a predetermined temperature.

5. The manufacturing method for the color photodiodes in parallel communication according to claim 4, wherein the step of transferring the integrated support dispensed and packaged into the baking equipment to bake and cure the integrated support at the predetermined temperature comprises:
baking the integrated support dispensed and packaged in a first stage, wherein in the first stage, a baking temperature is 60° C.-100° C., and a baking time is 60 minutes-80 minutes; and
baking the integrated support dispensed and packaged in a second stage, wherein in the second stage, a baking temperature is 140° C.-160° C., and a baking time is 60 minutes-80 minutes.

6. The manufacturing method for the color photodiodes in parallel communication according to claim 1, wherein after the integrated support cured and molded is cut, the manufacturing method further comprises:
baking the plurality of color photodiodes formed after cutting to remove a moisture produced in a process of cutting.

7. The manufacturing method for the color photodiodes in parallel communication according to claim 6, wherein the plurality of color photodiodes are baked at a temperature of 60° C.-100° C. and for 60 minutes-80 minutes.

8. A color photodiode manufactured by the manufacturing method for the color photodiodes in parallel communication according to claim 1.

9. A photoelectric display screen, wherein the photoelectric display screen has a plurality of color photodiodes according to claim 8, and the plurality of color photodiodes are driven by parallel communication.

10. The color photodiode according to claim 8, wherein in the manufacturing method for the color photodiodes in parallel communication, the step of fixing and installing the visible light emitting chip and the color control chip in each packaging cavity comprises:
dispensing a chip fixing adhesive at a first designated position and a second designated position in the packaging cavity respectively;
placing the red light emitting chip, the blue light emitting chip and the green light emitting chip at the first designated position, maintaining a predetermined distance, and bonding the red light emitting chip, the blue light emitting chip and the green light emitting chip with the chip fixing adhesive;
placing the color control chip at the second designated position, and bonding an induction chip with the chip fixing adhesive; and
delivering the integrated support into a curing device and baking the integrated support at a temperature of 150° C.-180° C. and for 60 minutes-80 minutes for curing.

11. The color photodiode according to claim 8, wherein in the manufacturing method for the color photodiodes in parallel communication, the plurality of pins comprise a positive power pin, a negative power pin, and a signal input pin; the color control chip comprises a positive terminal, a negative terminal, a signal input terminal, a first driving terminal, a second driving terminal, and a third driving terminal;
the step of welding the visible light emitting chip, the color control chip and the plurality of pins with the bonding wire to form the electric control loop comprises:
welding the positive terminal with the positive power pin, welding the negative terminal with the negative power pin, and welding the signal input terminal with the signal input pin;
electrically connecting the first driving terminal with a negative pole of the red light emitting chip, electrically connecting the second driving terminal with a negative pole of the green light emitting chip, and electrically connecting the third driving terminal with a negative pole of the blue light emitting chip; and
connecting a positive pole of the red light emitting chip, a positive pole of the green light emitting chip and a positive pole of the blue light emitting chip with the positive power pin.

12. The color photodiode according to claim 8, wherein in the manufacturing method for the color photodiodes in parallel communication, the step of dispensing the packaging cavity with the packaging adhesive and curing and molding comprises:
using an epoxy resin adhesive or a silica gel to dispense and package the packaging cavity; and
transferring the integrated support dispensed and packaged into a baking equipment to bake and cure the integrated support at a predetermined temperature.

13. The color photodiode according to claim 12, wherein in the manufacturing method for the color photodiodes in parallel communication, the step of transferring the integrated support dispensed and packaged into the baking equipment to bake and cure the integrated support at the predetermined temperature comprises:
baking the integrated support dispensed and packaged in a first stage, wherein in the first stage, a baking temperature is 60° C.-100° C., and a baking time is 60 minutes-80 minutes; and
baking the integrated support dispensed and packaged in a second stage, wherein in the second stage, a baking temperature is 140° C.-160° C., and a baking time is 60 minutes-80 minutes.

14. The color photodiode according to claim 8, wherein in the manufacturing method for the color photodiodes in parallel communication, after the integrated support cured and molded is cut, the manufacturing method further comprises:
baking the plurality of color photodiodes formed after cutting to remove a moisture produced in a process of cutting.

15. The color photodiode according to claim 14, wherein in the manufacturing method for the color photodiodes in parallel communication, the plurality of color photodiodes are baked at a temperature of 60° C.-100° C. and for 60 minutes-80 minutes.

16. The photoelectric display screen according to claim 9, wherein in the manufacturing method for the color photodiodes in parallel communication, the step of fixing and installing the visible light emitting chip and the color control chip in each packaging cavity comprises:
dispensing a chip fixing adhesive at a first designated position and a second designated position in the packaging cavity respectively;
placing the red light emitting chip, the blue light emitting chip and the green light emitting chip at the first designated position, maintaining a predetermined distance, and bonding the red light emitting chip, the blue light emitting chip and the green light emitting chip with the chip fixing adhesive;
placing the color control chip at the second designated position, and bonding an induction chip with the chip fixing adhesive; and
delivering the integrated support into a curing device and baking the integrated support at a temperature of 150° C.-180° C. and for 60 minutes-80 minutes for curing.

17. The photoelectric display screen according to claim 9, wherein in the manufacturing method for the color photodiodes in parallel communication, the plurality of pins comprise a positive power pin, a negative power pin, and a signal input pin; the color control chip comprises a positive terminal, a negative terminal, a signal input terminal, a first driving terminal, a second driving terminal, and a third driving terminal;
the step of welding the visible light emitting chip, the color control chip and the plurality of pins with the bonding wire to form the electric control loop comprises:
welding the positive terminal with the positive power pin, welding the negative terminal with the negative power pin, and welding the signal input terminal with the signal input pin;
electrically connecting the first driving terminal with a negative pole of the red light emitting chip, electrically connecting the second driving terminal with a negative pole of the green light emitting chip, and electrically connecting the third driving terminal with a negative pole of the blue light emitting chip; and
connecting a positive pole of the red light emitting chip, a positive pole of the green light emitting chip and a positive pole of the blue light emitting chip with the positive power pin.

18. The photoelectric display screen according to claim 9, wherein in the manufacturing method for the color photodiodes in parallel communication, the step of dispensing the packaging cavity with the packaging adhesive and curing and molding comprises:
using an epoxy resin adhesive or a silica gel to dispense and package the packaging cavity; and
transferring the integrated support dispensed and packaged into a baking equipment to bake and cure the integrated support at a predetermined temperature.

19. The photoelectric display screen according to claim 18, wherein in the manufacturing method for the color photodiodes in parallel communication, the step of transferring the integrated support dispensed and packaged into the baking equipment to bake and cure the integrated support at the predetermined temperature comprises:
baking the integrated support dispensed and packaged in a first stage, wherein in the first stage, a baking temperature is 60° C.-100° C., and a baking time is 60 minutes-80 minutes; and
baking the integrated support dispensed and packaged in a second stage, wherein in the second stage, a baking temperature is 140° C.-160° C., and a baking time is 60 minutes-80 minutes.

20. The photoelectric display screen according to claim 9, wherein in the manufacturing method for the color photodiodes in parallel communication, after the integrated support cured and molded is cut, the manufacturing method further comprises:
baking the plurality of color photodiodes formed after cutting to remove a moisture produced in a process of cutting.
